(19) United States
(12) Patent Application Publication
(10) Pub. No.: US 2014/0278163 A1
(43) Pub. Date: Sep. 18, 2014

(54) DISTRIBUTED SOLAR POWER GENERATION AND MONITORING SYSTEM

(71) Applicants: Harold Y. Tan, Los Angeles, CA (US); David Wayne Donaldson, Ventura, CA (US); Deep Patel, West Covina, CA (US)

(72) Inventors: Harold Y. Tan, Los Angeles, CA (US); David Wayne Donaldson, Ventura, CA (US); Deep Patel, West Covina, CA (US)

(73) Assignee: Gigawatt, Inc., Placentia, CA (US)

(21) Appl. No.: 13/841,770

(22) Filed: Mar. 15, 2013

(51) Int. Cl. G01R 21/133

(52) U.S. Cl. CPC G01R 21/133
USPC 702/60

(57) ABSTRACT

A system and method for a distributed solar power generation and communications system that includes one or more solar power generation and communications system units mounted on utility poles and distributed across a region. Each solar power generation and communications system unit includes one or more solar panels, a micro-converter, a meter, and a modem. Each unit is configured to communicate solar power production/consumption data to a remote monitoring and forecast system that estimates the unit's power production/consumption over a future period of time. A system and method is also provided for a solar power generation and communications system unit that includes a protective shroud and installation processes for mounting the unit on a utility pole and electrically coupling the unit to an utility electric grid.

### FIELD OF THE INVENTION

This invention relates generally to the field of solar power generation, and more specifically to a system for generating and/or monitoring and/or distributing electrical power that is produced from one or more solar power generation units that supply the electricity to an electrical utility grid.

### BACKGROUND

Solar power is the conversion of sunlight into electricity. Photovoltaics convert sunlight directly into electricity. Initially, photovoltaics were used to power portable, small and medium-sized applications like a calculator powered by a single solar cell or a home that is not attached to a traditional power grid and powered by a photovoltaic array. Solar cells arranged into an array (i.e., solar arrays) are a type of photovoltaic that is used to convert sunlight to electricity.

Solar cells produce direct current (DC) power which fluctuates with the sunlight's intensity. To use the electricity in practical ways, the DC power usually needs to be converted to certain desired voltages or alternating current (AC) via the use of inverters. Multiple solar cells are connected inside modules and modules are wired together to form a photovoltaic solar cell array. The output of the photovoltaic arrays is then tied to an inverter for producing an alternating current (AC) at the desired frequency/phase and power at the desired voltage. Once the solar power is converted to the desired form, phase and/or frequency, the electricity may be used for practical applications. One of the practical applications for this type of electricity is powering residential systems that are traditionally connected to a utility power grid.

Currently, entire residential communities are being powered in part by large scale photovoltaic power stations made up of large numbers of photovoltaic arrays. To bring solar power to communities such as business centers, residential communities, industrial communities and the like, large scale photovoltaic power stations are typically arranged in large wide open spaces that span many acres. The amount of land required to accommodate large scale photovoltaic power plants is a direct reflection of the sheer number of photovoltaic arrays required to produce the amount of electricity needed to power communities of consumers and the location of these power plants is indicative of the amount of sun exposure that is required to produce enough electrical energy to meet these consumer's needs. Some of the most well-known large scale photovoltaic power stations in the World include the Agua Caliente Solar Project (USA), the Charanka Solar Park (India), the Golmud Solar Park (China), and the Neuhardenberg Solar Park (Germany). There are also many large scale photovoltaic power plants under construction. For example, the Desert Sunlight Solar Farm is a 550 MW solar power plant under construction in Riverside County, California, that will use thin-film solar photovoltaic modules. The Topaz Solar Farm is a 550 MW photovoltaic power plant being built in San Luis Obispo County, California. The Blythe Solar Power Project is a 500 MW photovoltaic station under construction in Riverside County, California.

However, there are some disadvantages associated with these large scale power generation and distribution centers. To distribute the electricity generated by these types of large scale power plants, the electricity must typically be transported across large distances as these power plants are often times disposed in areas many miles from the end consumers, such as in the middle of a sun drenched dessert. The infrastructure required to transport the electricity produced by the power plants may become prohibitively expensive. Additionally, the energy loss that occurs during the transport of the electrical power is a direct result of the distances that are covered during the transport and the type of transmission lines used. Another hurdle to construction and far spread use of large scale photovoltaic power plants is high installation costs. Furthermore, due to the sheer quantity of photovoltaic solar arrays utilized in these large scale solar power plants, it is difficult to determine if one or more of the photovoltaic units out of the multitude of units that are employed is functioning properly and producing the correct amount of electrical energy.

One of the inherent limitations of generating electrical power using a photovoltaic device is that power is generated only during the times that sunlight is captured (i.e., during the day). As a result of this temporal limitation, it is advantageous to minimize the transmission losses incurred during the transport of the generated power to the end consumer.

Therefore, there is a need for smaller-scale solar power generation systems that may be disposed in one or more areas near the end consumer and the power grid to which that consumer is connected. One or more smaller-scale photovoltaic power generation units dispersed throughout an area and disposed near the end consumers of electricity and the power grid on which these consumers rely would provide electricity directly to the power grid or to an electrical storage device to power such things as structural lighting, street lamps, consumer goods, home appliances and the like. Disposing these photovoltaic power generation units near the utility grid also minimizes the transmission losses associated with solar power generation These photovoltaic units would be aesthetically pleasing as they would be disposed in plain sight and mounted on pre-existing structures throughout a residential/business community or a rural community that requires the sort of electricity distribution that one or more photovoltaic power generation units may provide.

There is also a need for a way to forecast and monitor energy production and consumption from a distributed, pole-mounted photovoltaic unit or solar power plant. By matching energy production data with other factors that impact sun light exposure upon the solar panels, such as weather patterns, it can be determined if there are any problems with the rate of solar power production thereby maximizing the return from a solar power plant.

There is also a need for a way to monitor electrical power transmission data so that it can be determined if any potential issues or concerns with one or more photovoltaic units within a brief period of time.

Additionally, there is a need for a mounting system that provides a mechanically sound and reliable process to connect a photovoltaic power generation unit to an existing structure, such as a light or electrical pole, that is easily employed to secure the photovoltaic power generation unit to the structure with minimal installation time and effort, and that can withstand phenomena that typically affect pole and other structurally mounted devices disposed outside and connected to metal and/or wooden structures of the type seen and used in residential, business and rural communities. These phenomena include but are not limited to continuous, ranging, and/or extreme weather conditions, impact events from objects coming into contact with the photovoltaic power generation unit due to all manner of reasons, and structural issues that adversely impact the mounting surface and/or structure to which the photovoltaic power generation unit is attached.

Furthermore, there is a need for an installation process for mounting the photovoltaic power generation unit using the mounting system and connecting the photovoltaic power generation unit to the pre-existing electrical grid that allows for the monitoring of electrical events, the forecasting of electricity generation, and/or the consumption and/or distribution of electrical power, and that includes a process that is neither prohibitively expensive nor complicated such that pre-existing electrical grid utility workers that are properly trained may properly perform.

### SUMMARY

A solar power generation and communications system includes one or more solar power generation and communications system units that include one or more solar panels, a micro-inverter, a meter, a modem, and a junction box and connector all disposed within, on or around a solar panel assembly frame and the one or more solar panels. The units are configured to mount to utility poles and communicate with remote monitoring and forecast system. The monitoring and forecast system is a computer that is programmed to estimate solar electrical production/consumption of one or more solar power generation and communications system units. The solar power generation and communications system can include one or thousands of units depending upon the requirements of the consumer(s). Each of the solar power generation and communications system units is electrically coupled to an electrical utility grid to produce electricity from sun exposure and transmit that same to the utility grid. Each of the one or more solar panels converts solar power to direct (DC) current electrical energy. The micro-inverter converts DC electrical energy to alternating current (AC) electrical energy and the AC electrical energy is put on the utility grid. The monitoring and forecast system has the ability to determine if each of the solar power generation and communications system units are working properly by estimating how much electrical power production/consumption will occur over a given period of time based upon weather data. Weather data may include one or more of cloud cover patterns, the positioning of the sun, the time of day, the time of year, etc.

A method for estimating power generation/consumption is provided which includes a monitoring and forecast system receiving current kWh solar power production/consumption values from one or more solar power generation and communications system units mounted on utility poles and connected to a utility grid and storing the current kWh solar power production/consumption values in a database. The monitoring and forecast system receives or determines the zip code of the relevant solar power generation and communications units. The monitoring and forecast system communicates via a network, such as a LAN, WAN or the Internet with one or more public weather databases to obtain the weather data, such as the current cloud cover pattern. The monitoring and forecast system also obtains forecasted weather data, such as cloud cover patterns, via a network, such as a LAN, WAN or the Internet from one or more public weather databases for a particular period in the future. The monitoring and forecast system compares the forecasted weather data, such as cloud cover patterns, with previously stored weather data, such as the cloud cover patterns previously stored, and determines if there is a match to the forecasted weather data. If there is not a match, the program ends and is cycled over to receive current kWh production/consumption data from the same or different solar power generation and communications unit. If a match is found, the monitoring and forecast system calculates the Forecasted kWh which equals the average of kWh produced during the historical cloud cover pattern period that matches the forecasted cloud cover pattern for the forecasted time period with weighting given to most recent data.

A method for estimating power generation/consumption is provided which includes a monitoring and forecast system receiving current kWh solar power production/consumption values from one or more solar power generation and communications units mounted on utility poles and connected to a utility grid and storing the current kWh solar power production/consumption values in a database. The monitoring and forecast system receives or determines the zip code of the relevant solar power generation and communications units. The monitoring and forecast system communicates via a network, such as a LAN, WAN or the Internet with one or more public weather databases to obtain the weather data, such as the current cloud cover pattern. The monitoring and forecast system also obtains forecasted weather data, such as cloud cover patterns, via a network, such as a LAN, WAN or the Internet from one or more public weather databases for a particular period in the future. The monitoring and forecast system compares the forecasted weather data, such as cloud cover patterns, with previously stored weather data, such as the cloud cover patterns previously stored, and determines if it has made a match to the forecasted weather data. If it has, then the monitoring and forecasting system calculates the average kWh produced during the historical cloud cover pattern that matches the forecasted cloud cover pattern for a forecasted period of time with weighting given to the most recent data. If the current kWh production and current cloud cover pattern is similar to the historical kWh production data with matching cloud cover, then the program ends and is cycled over to receive current kWh production/consumption data from the same or different solar power generation and communications unit. If the current kWh production and current cloud cover pattern is not similar to the historical kWh production data with matching cloud cover, then the monitoring and forecast system determines if the difference between the current kWh production and/or cloud cover pattern is similar to historical kWh production with matching cloud cover. If the comparison result is not within a predetermined limit, then an alert is sent or sounded meaning that one or more of the identified solar power generation and communications units is underperforming or over performing.

A method for installing a solar power generation and communications unit on a utility pole which includes creating a 1-inch hole at a pre-determined height in a utility pole, running a wire harness into the pole and down the pole interior and terminating the wire into the sidewalk utility electrical grid. The solar power generation and communications unit includes one or more solar panels, a micro-inverter, a meter, a modem, and a junction box and connector all disposed within, on or around a solar panel assembly frame and the one or more solar panels. The solar panel assembly frame is connected to a shroud assembly which includes a shroud, a skeleton and a bracket assembly. The bracket assembly is mounted on the utility pole and it may be secured with steel or high intensity nylon straps. The solar power generation and communications unit is hoisted up to the bracket assembly using a crane arm and either manually hoisting the same with cables or using a battery operated or electrical hoist. Once the unit is in position, the upper frame member of the skeleton is hooked to the upper bracket of the bracket assembly and the lower support arm of the skeleton is attached to the lower frame member. The upper bracket is then fixedly secured to the skeleton by one or more straps. The micro-inverter is plugged into a trunk line disposed between the upper and lower brackets of the bracket assembly. The shroud back portions are then connected to the solar power generation and communications unit and the unit including the micro-inverter is tested to make sure the unit is working properly.

A method for installing a solar power generation and communications unit onto a utility pole and electrically coupling the same to a utility grid including positioning a platform truck along the side of a utility pole, the platform truck including two (2) articulating platforms that articulate in a horizontal direction with respect to the ground. Both articulating platforms are at or about the same height that the solar power generation and communications unit will be mounted on the utility pole. The first articulating platform moves in a horizontal direction towards the pole to create a surface that is 180 degrees adjacent to the pole. The second articulating arm includes an elongated groove in the surface such that, due to the positioning of the platform truck, the second articulating platform is moved towards the utility pole and surrounds the pole on 3 sides. After the second articulating platform is in position, a trap door is closed to cover the elongated groove on the fourth remaining side of the pole to completely surround the utility pole and give workmen or workwomen a platform in which to mount a solar power generation and communications unit as described above without the need for a hoist and or crane arm.

A system for the installation of a solar power generation and communications unit onto a utility pole and electrically coupling the same to a utility grid is provided. The system includes a platform truck wherein the cargo portion of the truck is at or about the same height as the desired height that the solar power generation and communications unit will be mounted to a the utility pole. The platform truck includes two (2) articulating platforms that articulate in a horizontal direction with respect to the ground. Both articulating platforms are at or about the same height that the solar power generation and communications unit will be mounted on the utility pole. The first articulating platform moves in a horizontal direction towards the pole to create a surface that is 180 degrees adjacent to the pole. The second articulating arm includes an elongated groove in the surface such that, due to the positioning of the platform truck, the second articulating platform is moved towards the utility pole and surrounds the pole on 3 sides. After the second articulating platform is in position, a trap door is closed to cover the elongated groove on the fourth remaining side of the pole to completely surround the utility pole and give workmen or workwomen a platform in which to mount a solar power generation and communications unit as described above without the need for a hoist and or crane arm.

### BRIEF DESCRIPTION OF THE DRAWINGS

The accompanying drawings illustrate one or more embodiments of the invention and, together with the written description, serve to explain the principles of the invention. Wherever possible, the same reference numbers are used throughout the drawings to refer to the same or like elements of an embodiment, and wherein:

FIG. 1 illustrates an exemplary environment 100 for a pole mounted solar power generation and communications system in which various configurations and embodiments of the present invention can be deployed and utilized;

FIG. 2 illustrates a block diagram of a solar power generation and communications system unit in accordance with one embodiment of the present invention;

FIGS. 3 and 4 illustrate respective flowcharts of a method for solar power generation monitoring and forecasting in accordance with another embodiment of the present invention;

FIG. 5 illustrates a distributed solar power generation and communications system unit in accordance with another embodiment of the present invention;

FIG. 6A illustrates a perspective view of a shroud assembly;

FIG. 6B illustrates a bottom view of a shroud assembly and a distributed solar power generation and communications system unit;

FIG. 6C illustrates a bottom view of a shroud assembly and a distributed solar power generation and communications system unit;

FIG. 6D illustrates a perspective view of a shroud assembly and a distributed solar power generation and communications system unit;

FIG. 6E illustrates an exploded view of a shroud assembly;

FIG. 6F illustrates a side view of a bracket assembly;

FIG. 6G illustrates perspective views of an upper bracket and lower bracket;

FIG. 6H illustrates a cross-sectional view of a distributed solar power generation and communications system unit;

FIG. 7 illustrates a back portion of a distributed solar power generation and communications system unit with part of the shroud removed;

FIG. 8 illustrates a flowchart of a process for installing a solar power generation monitoring and forecasting unit on a utility pole in accordance with another embodiment of the present invention;

FIG. 9 illustrates a perspective view of a crane arm utilized in the process of installing a solar power generation monitoring and forecasting unit on a utility pole in accordance with another embodiment of the present invention; and

FIG. 10 is a perspective view of a platform truck and articulation system utilized in the process of installing a solar power generation monitoring and forecasting unit on a utility pole in accordance with another embodiment of the present invention.

### DETAILED DESCRIPTION OF EMBODIMENTS OF THE INVENTION

FIG. 1 illustrates an exemplary environment 100 for a pole mounted solar power generation and communications system in which various embodiments of the present invention can be deployed and utilized. The solar power generation and communications system includes one or more decentralized solar power generation and communications system units 102 and 104. Although two (2) solar power generation and communications units are shown in FIG. 1, the FIG. 1 embodiment of the present invention may operate with just one solar power generation and communications system unit 102. Additionally, the present invention is also configured to operate with thousands of solar power generation and communications system units mounted on utility poles and distributed across a region as small as a neighborhood and as vast as the United States.

As shown in FIG. 2, each of the solar power generation and communications system units 102, 104 of the one embodiment of the present invention includes one or more solar panels 204 that are configured to convert sunlight to electrical power, a converter such as a micro-inverter 206 for converting DC power to certain desired voltages and an alternating current (AC) in preparation for distributing the generated electricity on the utility grid 106, a mounting bracket (not shown) configured to securely mount each of the solar power generation and communications system units 102 and 104 to a utility pole such as, for example, a street light pole (as shown in the present example of FIG. 1), telephone pole, traffic signal pole, or any pole-like structure that is electrically connected to a utility grid, a modem 210 configured to communicate with other solar power generation and communications systems and servers maintained on a network such as a WAN (wide-area network), LAN (local-area network), or the Internet, and a meter 208 for monitoring and reporting solar power generation and utility grid parameters. Although FIG. 1 illustrates two solar power generation and communications system units, it will be apparent to those having ordinary skill in the art that the present embodiment may include any number of solar power generation and communications systems depending upon the needs of the consumers, the environment in which electrical power is desired, and power requirements of the consumers in the region. Examples of the type of applications for which the solar power generation and communications system of the present invention may be used include but are not limited to utility pole electricity generation such as street lights and traffic signals, households and household goods and appliances, electrical power generation for towns, cities, industrial sites, agricultural sites, civilian and industrial equipment, etc. Consumers of the electricity generated by the solar power generation and communications systems may include any electrical system or device that is configured to plug into a utility grid that may utilize electricity generated by one or more solar power generation and communications systems.

FIG. 2 illustrates a block diagram of a solar power generation and communications system unit 102, 104 illustrated in FIG. 1 in accordance with an embodiment of the present invention. The solar power generation and communications system unit 200 includes a solar panel assembly frame 202, one or more solar panels 204, a micro-inverter 206, a meter 208, a modem 210, a junction box and connector assembly 214, and a remote monitoring and forecast system 212. The elements described above may be included in a single solar panel assembly or may operate as entities separate and apart from the solar panel assembly. For example, the junction box 214 and/or the micro-inverter 206 may be mounted on the utility pole, on the solar panel assembly frame 202, or outside and apart from the solar panel assembly frame and the utility pole. The one or more solar panels 204 included in the solar power generation and communications system unit 200 are configured to receive solar energy from the sun and convert the solar energy to direct current (DC) electrical energy. In one embodiment of the present invention, the solar panel(s) 204 is a 235 Watt solar panel. A person having skill in the art would appreciate that other types of solar panels may be utilized in the present invention if they are functional to generate solar power within a pole mounted solar power plant as described herein. Once the one or more solar panels 204 generate the electrical energy, the DC electrical energy is transmitted to the micro-inverter 206 wherein the DC electrical energy is converted into alternating current (AC) electrical energy.

Although the inverter used to convert the DC electrical energy is into alternating current (AC) electrical energy is described as a micro-inverter, any inverter that is configured to operate with solar panels utilized in any of the embodiments of the present invention may be utilized. In one embodiment of the solar power generation and communications system, the micro-inverter is used as the inverter to convert the DC electrical energy is into alternating current (AC) electrical energy. The solar panel assembly frame of the embodiment shown in FIG. 2 is configured to accommodate variations in size, shape, and heat dissipation requirements of various types of inverters. In another embodiment of the present invention, the meter 208 is a web-enabled Revenue Grade Meter (RGM) that can monitor and transmit the solar power generation and communications system parameters and utility grid parameters. In this embodiment, meter 208 measures the power production of the solar power generation and communications system unit in kWh and forwards the data to modem 210 for transmission to a remote monitoring system over the Internet or other network such as a LAN or WAN.

Once the DC electrical energy is converted to AC electrical energy and transformed to comply with the applicable standards for supplying a utility grid with electricity including the proper voltage, frequency, phase, etc, the AC electrical energy is transmitted via meter 208 to the utility pole to which the solar power generation and communications system unit is attached to provide power directly to the same or directly to the utility grid. In another embodiment of the present invention, meter 208 may determine if any energy output by the micro-inverter 206 should be stored in a battery, on the utility grid, or another applicable and suitable energy storage device.

In another embodiment of the present invention, the solar power generation and communications system can include a remote monitoring and forecast system 212 that includes one or more computers programmed to monitor one or more solar power generation and communications system units. The monitoring system 212 may measure power generation and output, voltage and current levels, phase and frequency, metering functionality, etc, The monitoring system 212 receives electricity production data from the solar power generation and communications system unit that has been transmitted to the remote monitoring system via the modem 210 or other suitable communications device, over a network (e.g., WAN, LAN, the Inernet, etc.). The monitoring system 212 can also monitor grid parameters such as cycles, voltage and current, display power production summaries, and/or detect abnormal drops in power production. The monitoring system 212 is configured to act in an individual capacity and drill-down to an individual circuit in one solar panel assembly used in one solar power generation and communications system units or look at an entire region of solar power generation and communications system units 202 included in multiple solar power generation and communications systems distributed across one or more regions. These power production summaries may be created to display results daily, weekly, monthly, yearly, between date ranges, or across smaller temporal ranges occurring within a day (e.g., hours and/or minutes). The monitoring system can also generate notification alerts and/or reports, the reports describing possible maintenance issues. In another embodiment of the present invention, the data output by the meter 208 may be transmitted via transmission lines included in the utility grid or transmitted wirelessly depending upon the location of the remote monitoring system and the environment in which the solar power generation and communications system unit is disposed.

The remote monitoring and forecast system 212 will be described below with reference to FIG. 3. The remote monitoring and forecast system 212 used in one embodiment of the present invention can estimate the power production of individual solar power generation and communications system units or multiple solar power generation and communications system units distributed across a region for a future period in time (i.e., a day, a range of hours, etc.) using weather data based upon the current weather conditions and predicted weather predictions in the form of weather forecast and/or reports. For example, in one embodiment of the present invention, the remote monitoring and forecast system 212 is one or more computers programmed to perform electrical energy production forecast or estimates. The remote monitoring and forecast system 212 will output a measurement in kilowatt-hour (kWh) that one or more selected solar power generation and communications system units should generate based on the current weather data and/or the predicted weather conditions. In another embodiment of the present invention, each solar power generation and communications system unit could be configured to transmit the required data at a pre-determined time period such that the remote monitoring and forecast system 212 will automatically output an estimate that measures the amount of power generation that should occur at that solar power generation and communications system unit.

In one embodiment of the present invention, the weather data used by the remote monitoring and forecast system 212 to predict the output of one or more solar power generation and communications system units is cloud cover. In this embodiment, one or more of the solar power generation and communications systems has cloud cover patterns stored in the control system 208 and/or a remote database (not shown) and the cloud cover patterns are used to determine how much electrical energy will be generated by the solar power generation and communications system over a future period of time. Each of the cloud cover patterns are associated with a power generation value or range of power generation values expressed in standardized units such as kWh. However, depending upon how accurate one of skill in the art desires the power estimation measurements to be, additional weather, environmental and/or temporal data may be collected and used to estimate the power generation of one or more solar power generation and communications systems. For example, the remote monitoring and forecast system 212 may be configured to store at various temporal intervals, for one or more solar power generation and communications systems, cloud patterns that are present in the relevant area that may be impacting the one or more solar panels' exposure to the sun, a solar power generation and communications system's current power generation, the position of the sun, and/or the calendar day and/or the time of day. One or more of these values can be stored in a database structure. One example of such a structure is a look-up-table but other structures are well known in the art and will not be discussed herein. This type of data may be generated and stored in a database in predetermined incremental periods of time such, as for example, every 15 minutes. Other periods of time may be used and are within the scope of the present invention. These periods of time include but are not limited to 1 minute to 1 day, depending upon the size of the database and the accuracy required for the power production estimation. In another embodiment of the present invention, these aforementioned values may be transmitted by one or more solar power generation and communications systems via modem 210 over a LAN, WAN or the Internet, or wirelessly, as described above, to a remote database accessed by remote monitoring and forecast system software running on a remote computer. The remote monitoring and forecast system 212 will estimate the power production for one or more solar power generation and communications systems in a given region for a future period in time.

FIG. 3 is a flowchart illustrating a method used by one embodiment of the present invention for estimating power generation of one or more solar power generation and communications systems over a future period in time. To describe the method, reference will be made to FIGS. 1 and 2 although it will be apparent to those skilled in the art that the illustrated method and variations of the same are applicable to various other embodiments of the present invention described herein. Such embodiments are also within the scope of the present invention.

Beginning at step 302 in FIG. 3, one or more of the solar panels 208 disposed within the solar panel assembly 202 of a solar power generation and communications system unit 200 mounted on a utility pole may or may not be receiving solar energy. In one embodiment, the solar power generation and communications system is configured to transmit its solar energy production determined by meter 208 at a pre-determined temporal interval to a remote monitoring system over a LAN, WAN or the Internet, or wirelessly, as described above. For example, in this embodiment of the present invention, each solar power generation and communications system unit 200 will transmit solar power generation data every 15 minutes. Once this information is received by the remote monitoring system, the current solar power production data for the relevant solar power generation and communications system is stored in a database controlled by the remote monitoring system. This is denoted at process step 304 in FIG. 3. The remote monitoring and forecast system 212 will determine from information included in the transmitted data which solar power generation and communications system unit 200 transmitted the data and where that unit resides. Using this data, the remote monitoring and forecast system 212 will at each predetermined interval, via the Internet or other available network, connect to one or more publicly available weather databases to obtain the current cloud cover pattern for the zip code matching the relevant solar power generation and communications system's zip code in the database and store the same information in a database. This is denoted at process step 306 in FIG. 3.

Again, this interrogation of one or more publicly available weather database may occur at different time intervals or may occur each time a solar power generation and communications system unit transmits its solar power generation data to the remote monitoring system. The database controlled by the remote monitoring system includes historical weather data and solar power generation data that includes measurements of solar power generation for different patterns of cloud cover for various area codes that one or more of the units 200 are or have been disposed. Thereafter, the remote monitoring and forecast system 212 will at each predetermined interval, via the Internet or other available network, connect to one or more publicly available weather databases to obtain forecasted cloud cover patterns for the zip code matching the relevant solar power generation and communications system's zip code in the database that represents predicted weather data for a pre-determined period of time in the future and store the same information in a database. This is denoted at process step 308 in FIG. 3.

Once the forecasted cloud cover pattern is received by the remote monitoring and forecast system 212 for a pre-determined interval of time in the future, the remote monitoring and forecast system 212 may determine if the newly received forecasted cloud cover pattern has been previously recorded in the database controlled by the remote monitoring system at step 310 of FIG. 3. In this instance, a comparison is made between the forecasted cloud cover pattern and cloud cover patterns found in the historical data to determine if there are one or more matches. If not, then the remote monitoring and forecast system 212 determines that no forecast is available at step 312 of FIG. 3 and ends the power generation forecast process for this cycle. If on the other hand the remote monitoring and forecast system 212 determines that there is one or more matches in the historical database, then the kWh production for all of the matches are averaged for a pre-determined time period with weighting given to matches within a pre-determined most recent time period. This process occurs at process step 314. The value of kWh production for that time period output by the averaging calculation is the Forecasted kWh value output at step 314 and this value is used to send an alert if one or more solar power generation and communications system units 200 are underperforming or over performing.

FIG. 4 is a flowchart illustrating a method used by another embodiment of the present invention for estimating power generation of one or more solar power generation and communications system units for a future period in time. To describe the method, reference will be made to FIGS. 1, 2 and 3 although it will be apparent to those skilled in the art that the illustrated method and variations of the same are applicable to various other embodiments of the present invention described herein. Such embodiments are also within the scope of the present invention. It is important to note here that method steps 402, 404, 406, 408, 410, 412 and 414 are substantially similar to method steps 302, 304, 306, 308, 310, 312 and 314, respectively, of the method for estimating power generation of one or more solar power generation and communications system units for a future period in time as described in FIG. 3. Therefore, method steps 416 and 418 will be described in detail below.

Once it is established that no historical data exists in the database for the forecasted cloud cover pattern received at step 408 in FIG. 4 and no forecast is available at step 412 in FIG. 4, the remote monitoring and forecast system 212 looks up all historical cases of kWh production/consumption that are associated with a “cloudy” cloud pattern. The system 212 will then average these numbers and compare it to the current kWh value obtained at step 404 in FIG. 4. If there is a difference of more than a predetermined percentage value between the forecasted kWh production/consumption value and the current kWh production/consumption value, then an alert is raised at step 418 of FIG. 4. The alert may come in the form of a message to one or more computer terminals remote from the unit 200, or may come in the form of a printed message to one or more printers connected to one or more computer terminals, or in any way known to those having ordinary skill in the art.

An example of the process described in the method of FIG. 4 for estimating power generation of one or more solar power generation and communications system units for a future period in time will now be provided. The following example is for exemplary purposes only and is not intended to limit the scope of the present invention to these one or more embodiments discussed herein. At step 402, the remote monitoring and forecast system 212 starts executing the software program. The system 212 either polls one or more solar power generation and communications system units 200 every 15 minutes or the units 200 are programmed to send automatically send kWh production/consumption data to the system 212 every 15 minutes. At step 404, system 212 receives electrical energy production/consumption data at 1:15 PM stating that an identified solar power generation and communications system unit 200 produced around 0/043 kWh in a 15 minute interval. In another embodiment of the present invention, this interval may be 30 minutes, an hour, a multiple of hours, a day, etc. In addition to the power generation data, the system 212 also determines the zip code of the identified solar power generation and communications system unit 200 either by looking up the zip code in a database or receiving the zip code from the unit 200. At step 406, the system 212 communicates with a public weather database such as weather.com API or http://www.wunderground.com/weather/api/?ref=twc to receive the current cloud cover pattern matching the zip code for the relevant unit 200. The cloud cover pattern received at step 406 is a numerical/textual representation of the cloud cover pattern and it is stored in a database. One having ordinary skill in the art appreciates that there are numerous ways to quantify cloud cover patterns and these quantifications are in the scope of the present invention. For example, Cloudy may be expressed as 9/10 to 10/10 opaque clouds as described by the public weather database www.nws.noaa.gov/wsom/manual/archives/NC118411.html#z8-6.

At step 408, the forecasted cloud cover pattern for a period of one day ahead of the current time matching the zip code of the identified unit 200 is received from a public weather database such as weather.com API or http://www.wunderground.com/weather/api/?ref=twc. In another embodiment of the present invention, this interval may be any interval between one hour and 10 days. At step 410, the system 212 compares the forecasted cloud cover pattern matching the identified unit's 200 zip code to previously stored cloud cover patterns for 1:00 PM to account for the 1:15 PM transmission of power generation/consumption data from the identified unit received in step 404. If a cloud cover pattern has not been previously stored in the database for the current cloud cover pattern, the system 212 will look at all historical cases that are stored in the database and average the number at step 416. So, for example, if at 1:15 PM the current condition is “Cloudy”, the system 212 looks up all historical cases of kWh production/consumption when it is “Cloudy” for 1 PM. The system 212 averages this number, taking into account month and year, and compares it to the current kWh number, in this instance 0.043 kWh. This calculation refers to step 416 of the method of FIG. 4. Once this calculation is determined, if there is a difference of more than 20% between the current and averaged electricity production/consumption value, an alert is raised at step 418 of the method described in FIG. 4. Those having skill in the art appreciate that the percentage range used to sound alerts may be any range above 1%. Each cloud cover pattern is quantified to national weather service standards as outlined in http://www.nws.noaa.gov/wsom/manual/archives/NC118411.HTML#z8-6.

An example of database entries that system 212 may use to perform the comparison in step 418 are as follows:

CONDITION: PARTLY CLOUDY

| YEAR | MONTH | HOUR | KWH_DEL | KWH_REC |
|---|---|---|---|---|
| 2012 | September | 15 | 0.3010667 | 0.0000000 |
| 2012 | September | 16 | 0.2264615 | 0.0000000 |
| 2012 | September | 17 | 0.1488889 | 0.0000000 |
| 2012 | September | 18 | 0.0152727 | 0.0000000 |
| 2012 | September | 19 | 0.0000000 | 0.0000000 |
| 2012 | September | 20 | 0.0000000 | 0.0000000 |

On other hand, if the forecasted cloud cover pattern has been previously recorded in the database, then the Forecasted kWh is calculated for the identified solar power generation and communications system unit 200 in accordance with step 414 of FIG. 4. For example, let's assume that tomorrow's weather is “Partly Cloudy”. Tomorrow's kWh=average kWh/per day for last 20 “Partly Cloudy” entries are weighted by 40% as 40% weighting is given to entries that have occurred in the past 7 days. Weighted Avgₓ=w₁x₁+w₂x₂ . . . wₙxₙ, where w=relative weight(%) and x=the solar production/consumption value. In this scenario, if the forecast is for tomorrow, then it is averaged out over a day. If the forecast is for the next hour, then it is averaged out on a per hour basis. The monitoring and forecast system 212 thereafter goes to step 416 and the following steps discussed above.

It will be appreciated that although the solar panel assembly frame 202 is configured to withstand the normal wear-and-tear and adversities that may come to impact a utility pole-mounted solar power generation unit, there is a need to provide more protection to these solar panel power plants to protect it against unseen nuances such as birds, extreme weather, and provide more secure mounts to utility poles than used in conventional mounting systems. Referring to FIGS. 2, 5 and 6A-6D, FIG. 5 illustrates a utility pole 504, and a solar power generation and communications system unit 502 mounted on utility pole 504. In this embodiment, solar power generation and communications system unit 502 includes a solar panel assembly frame 202 mounted on a shroud assembly 600 shown in FIG. 6A. The shroud assembly, as will be described in more detail with reference to FIGS. 6A-6D, is configured to surround the entire solar panel assembly 202 to better protect it against wildlife and extreme weather, and provide for a more secure connection to a utility pole.

As shown in FIG. 6A, the shroud assembly 600 includes a shroud 602 and a skeleton 604. When assembled, the shroud assembly 600 is configured such that the solar panel assembly 202 is securely mounted to skeleton 604. As is shown in FIGS. 6B, 6C and 6D, the shroud 602 protectively covers at least a portion if not all of the bottom of the solar panel assembly 202 and a substantial portion of the back of the solar panel assembly 202. As is shown in FIGS. 6A and 6E, skeleton 604 includes a symmetrical upper frame member 610, a lower support arm 612, and a bracket assembly 614. Upper frame member includes straight frame members 606A, 606B, and 606C of different lengths and bent joints 608A, 608B, and 608C of differing angle. When connected as shown in FIGS. 6A and 6E, the straight frame members 606A, 606B, 606C, and bent joints 608A, 608B and 608C come together to form a symmetrical top upper frame member 610 and lower support arm 612 is configured to be fixedly secured to one end of the upper frame member 610 and to releasably engage the bracket assembly 614. Those having skill in art know that any conventional means of fixedly securing the lower support arm 612 to the upper frame member 610 may be used including but not limited to bolts, screws, welding, press fit, frictional fit, etc.

As shown in FIGS. 6F, bracket assembly 614 includes C-channel bracket 616, upper bracket 618, and lower bracket 620. As is shown in FIG. 6D, C-channel bracket 616 has a groove formed in its length and is shaped like a C if viewed from a side angle. C-channel bracket 616 is configured to engage a utility pole such that the coupling between the bracket assembly 614 and a utility pole resist rotational translation of solar power generation and communications unit 502 around a utility pole. As shown in FIG. 6G, upper bracket 618 includes a hook portion 622 disposed on one side thereof, an engaging member 624 disposed on the top thereof, a back portion 628, and a groove portion 626 formed in the back portion 628. As shown in FIG. 6H, upper bracket 618 is mounted upon and secured to the top portion of C-channel bracket 616 by engaging member 624 sliding into elongated groove 630 of C-channel bracket 616. Upper bracket 618 may be secured to C-Channel bracket 616 in many ways known to those having skill in the art including but not limited to press fitting, frictional fitting, bolts, nuts, screws, welding, etc. As shown in FIGS. 6E and 6H, hook portion 622 of upper bracket 618 is configured to releasably engage straight member 606C of upper frame member 610 such that upper frame member 610 is pivotably supported in hook portion 622. In one embodiment of the present invention, upper frame member 610 is detachably secured to upper bracket 618 such that solar power generation and communications unit 502 may be removed from bracket assembly 614 and thus released from the utility pole. In another embodiment of the present invention, upper frame member 610 may be permanently secured to upper bracket 618 by conventional means understood by those having skill in the art including welding, press fit, frictional fit, bolts, screws, etc. once solar power generation and communications unit 502 is mounted to the utility pole.

As shown in FIGS. 6G and 6H, lower bracket 620 includes a top extending portion 632, a bottom extending portion 634, a front groove portion 636 disposed between top extending portion 632 and bottom extending portion 634, a back portion 638, and a back groove portion 640 disposed within back portion 638. As shown in FIG. 6H, lower bracket 620 is affixed to the back portion of C-channel bracket 616. It is understood by those having skill in the art that lower bracket 620 may be affixed to C-channel bracket 616 by conventional means understood by those having skill in the art including welding, press fit, frictional fit, bolts, screws, etc. As shown in FIGS. 6A, 6E and 6H, lower bracket 620 is also configured to releasably secure lower support arm 612.

As shown in FIG. 6E, the shroud 602 includes shroud side portions 642, that come together to cover at least a portion of the back of solar panel assembly frame 202, and shroud back portions 644 that operate to cover substantially the entire back of solar panel assembly frame 202. It will be appreciated from the above from those having skill in the art that the shroud serves to protect the solar power generation and communications system units by acting as an extra barrier of protection substantially encasing the solar panel assembly frame 202 within the same. The shroud may be made of plastic, light weight metal, or any material configured to meet the weight requirements of a pole mounted solar power plant and provide the protection required to withstand the environment in which the solar power plant is disposed. Additionally, once this embodiment of solar power generation and communications system unit 502 of the present invention is mounted to a utility pole, micro-inverter 206 may be disposed inside of solar panel assembly frame 202, inside shroud assembly 600, or configured to be plugged into a connector disposed within shroud assembly 600 to communicatively couple with solar power generation components as described above with respect to FIG. 2. In one embodiment of the present invention, skeleton 604 may be entirely made of metal. However, one of ordinary skill will appreciate that skeleton 604 may also be made of high density plastics and PVCs, or a combination of plastic and metal depending upon the environmental restrictions and the available materials.

As is shown in FIGS. 5 and 6C, shroud assembly 600 is configured to fixedly secure a solar power generation and communications unit 502 to a utility pole at an angle. One embodiment of the present invention positions power generation and communications unit 502 at an angle of 34 degrees down from the horizon such that the one or more solar panels 204 utilized in the unit directly face the sky and are subject to maximum sun exposure over a pre-determined time period. However, any angle that exposes the solar panel(s) to maximum or near maximum sun exposure over any predetermined time period is within the scope of the present invention.

The process steps recited in FIG. 9 will be described in detail with continued reference to FIGS. 6-9 to describe one embodiment of a process for installing one or more embodiments of a solar power generation and communications unit of the present invention. Where needed, reference will also be made to FIG. 10 which illustrates another embodiment of a process for installing one or more embodiments of a solar power generation and communications unit of the present invention. Beginning at step 802 recited in the flow chart illustrated in FIG. 9, a hole is created in a utility pole with an approximately 1-inch thick diameter approximately eighteen (18) feet up the pole when measured from the ground. Depending upon the type of wires used to connect solar power generation and communications unit 502 to the utility grid, the hole may be made substantially larger or smaller. In this particular example, it was determined that placing the back of solar power generation and communications unit 502 at the 18 foot mark was optimal to achieve maximum sun exposure upon the one or more solar panels 204. One having ordinary skill in the art would know that the optimum height and the angle of positioning in which the solar power generation and communications unit 502 is disposed may depend upon the location within in a region such as the United States that the same is located and the time of year the unit is functioning. Therefore, placing the unit 502 at different heights is within the scope of the present invention. At steps 804 and 806, a wire harness is run into the hole down the interior of the utility pole and is terminate into the sidewalk utility grid circuit. One having ordinary skill in the art knows that a person may be raised and lowered to perform work on a utility pole using a conventional “bucket” truck that utilizes an articulating arm to position the individual to an optimal position in relation to the pole and the work required to be performed.

At process step 808, bracket assembly 614, as shown in FIG. 6F, is secured to the utility pole and positioned such that elongated groove 630 of C-channel bracket 616 engages the utility pole. In one embodiment of the present invention, C-channel Bracket assembly 614 is bolted onto the utility pole. As discussed above, one having ordinary skill in the art would appreciate that other conventional ways of fixedly securing Bracket assembly 614 to the utility pole are well known. Additionally, bracket assembly is secured to the utility pole by utilizing steel straps. As is seen with respect to FIG. 6F, upper bracket 618 and lower bracket 620 each have back portion grooves 626 and 640 respectively. When bracket assembly 614 is secured to the utility pole, steel straps configured to fit in and through back portion grooves 626 and 640 and around the utility pole and tightened to fixedly secure bracket assembly 614 to the utility pole. A tensioning tool such as a Band-It™ tensioning tool or other known conventional tool may be utilized to tighten the steel straps. Those having skill in the art will appreciate that straps made of different and varying materials may be used to achieve the same tension to secure bracket assembly 614 to the utility pole and are within the scope of the present invention. Bracket assembly may be place just higher than or just lower than the hole disposed at eighteen (18) feet up the utility pole depending upon the disposition of solar power generation and communications unit 502.

Step Solar power generation and communications unit 502 is hoisted into position. This is denoted at process step 810. Step 810 may be performed by a crane arm such as the crane arm illustrated in FIG. 9. As is seen with respect to FIG. 9, crane arm 900 includes top bar 902 having a first end 904 and second end 906, t-bar 908 having a first end 910 and a second end 912, a cross-bar 914 having a first end 916 and a second end 918. T-bar 908 is fixedly connected to top bar 902 at its first end 910 and fixedly connected to cross-bar 914 at its second end 912. Cross-bar 914 is fixedly secured at its first end 916 to top bar 902 at a position along the length of and between the top bar first end 904 and second end 906. As is shown in FIG. 9, hooking mechanisms 920, 922 and 924 are fixedly secured by to top bar 904 and cross bar 914. In one embodiment of the present invention, crane arm 900 is rested on top of bracket assembly 614 and secured to the utility pole by conventional means including, but not limited to, steel straps of the kind described above, high intensity mesh straps, bolts, screws, etc. One or more rigging attachments (not shown) are connected to the shroud 602 of solar power generation and communications unit 502. Cables are then placed through the hooking mechanisms 922 and 924 and the rigging attachments connected to the shroud 602 in such a manner that pulling on the cables will result in the unit 502 raising up the utility pole to the height of bracket assembly 614. This is also denoted at process step 810. Those having skill in the art appreciate that a battery operated or other powered hoist may be employed and such use of these conventional tools are within the scope of the present invention.

Once solar power generation and communications unit 502 is raised to the requisite level and positioned such that straight frame member 606C is in alignment with upper hook portion 622 of upper bracket 618, straight frame member 606C of skeleton 604 is releasably engaged onto upper hook portion 622 of upper bracket 618 at process step 812. Once the unit 502 is connected to upper bracket 618, unit 502 is lowered at its unsecured end to secure the free end of lower support arm 612 to lower bracket 620 within front groove portion 636 as shown in FIGS. 6A and 6H as recited in process step 814. At process step 816, upper bracket 618 is fixedly secured to skeleton 604 by strapping upper bracket 618 to skeleton 604. For example, straight frame members 606A, 606B or 606C may be utilized as securing members around with to tie or torque a strap to fixedly secure upper bracket 618 to skeleton 604. At process step 818, micro-inverter 206 is plugged into a trunk line connector disposed between the upper and lower brackets 618, 620 of the bracket assembly. At process step 820, shroud back portions 644 as seen in FIG. 6E are placed and secured in their respective positions as seen in FIG. 6D to protect the solar panel assembly 202. At process step 822, solar power generation and communications unit 502 is tested to ensure proper operation. For example, testing could occur to ensure micro-inverter 206 is working properly.

In another embodiment of the present invention, a truck 1000 that includes a first articulating platform 1010 and a second articulating platform 1020, that moves in a horizontal direction relative to the first articulating platform 1010, may be utilized to mount solar power generation and communications unit 502 to a utility pole. As is seen with respect to FIG. 10, first and second articulating platforms 1010 and 1020 are of a height that is at or near the desired height that unit 502 will be placed on the utility pole. As one having skill in the art appreciates, utilizing platform truck 1010 of the present embodiment will remove the necessity of using a hoist and/or pulley system to lift and position unit 502 in place for mounting the same on a utility pole. In this embodiment, articulating platform 1020 includes a groove 1022 that is configured to engage the utility pole as articulating platform 1020 translates in the horizontal direction. In operation, platform truck 1000 moves along side a utility pole and positions the cargo hold of the truck such that the groove 1022 of second articulating platform 1020 is dead center with the utility pole. Articulate the first articulating platform 1010 in a horizontal direction such that it makes contact with or is close to making contact with the utility pole and provides a 180 degree surface in relation to the utility pole. The next step is to articulate second articulating platform in the horizontal direction in relation to first articulating platform such that the utility pole is positioned within elongated groove 1022 of second articulating platform 1020. The next step is to secure the utility pole within elongated groove 1022 with the use of a panel or trap door (not shown) that will lie across elongated groove 1022 and provide a continuous surface for a user to walk upon while preventing a user from falling into elongated groove 1022. In this manner, steps 810 of the process flow chart illustrated in FIG. 9 is removed resulting in faster and safer installation of solar power generation and communications units onto utility poles.

It will be evident to those having skill in the art that there are numerous embodiments of the present invention which, while not specifically described, are clearly within the scope and spirit of the present invention. Consequently, the above description is considered to be exemplary only, and the full scope of the invention is to be determined solely by the appended claims.

We claim:

1. A method for estimating solar power generation by a computer system of a solar power generation unit having an input unit, a storage unit, and a processing unit, the method comprising:
receiving input data at the input unit, wherein the input data comprises:
current kWh production data from a solar power generation unit;
a zip code associated with the solar power generation unit;
current weather data associated with the zip code from a weather database;
forecasted weather data associated with the zip code, the forecasted weather data representing predicted weather data for a pre-determined time period in the future;
compiling by the processing unit a database from the current kWh production data, the zip code, and current weather data associated with the respective forecasted weather data;
storing the database on the storage unit;
comparing, by the processing unit, the forecasted weather data to the current weather data; and
estimating the average kWh production that the solar power generation unit should produce over the pre-determined time period based on the comparison of the forecasted weather data to the current weather data.
